(19) United States
(12) Patent Application Publication
(10) Pub. No.: US 2023/0301005 A1
(43) Pub. Date: Sep. 21, 2023

(54) METHOD OF DISPLAYING A PORTABLE ARTICLE

(71) Applicant: SE-KURE CONTROLS, INC., Franklin Park, IL (US)

(72) Inventors: Roger J. Leyden, Inverness, IL (US); Lazaro Fraiman, Skokie, IL (US); Jorge L. Meza, Westchester, IL (US)

(21) Appl. No.: 18/201,873

(22) Filed: May 25, 2023

Related U.S. Application Data
(62) Division of application No. 16/239,201, filed on Jan. 3, 2019, now abandoned.
(60) Provisional application No. 62/668,509, filed on May 8, 2018.

(51) Int. Cl. H05K 7/14; A47F 7/00; G08B 13/14; H01R 33/97; H01R 13/516; E05B 73/00

(52) U.S. Cl. CPC H05K 7/1401; A47F 7/00; G08B 13/1463; H01R 33/97; H01R 13/516; E05B 73/0082

(57) ABSTRACT

A method of displaying a portable article having a body with a peripheral edge. A support assembly with a frame, fixed relative to a support, is obtained having U-shaped receptacles and a blocking assembly. The portable article is slid guidingly against the support assembly in a first direction consistently along a predetermined first path from a pre-assembly position into a display position. With the blocking assembly in a first state, the blocking assembly does not interfere with guided movement of the portable article oppositely to the first direction from the display position. With the blocking assembly changed into a second state, movement of the portable article in the display position along the predetermined first path oppositely to the first direction is blocked.

### BACKGROUND OF THE INVENTION

### Cross-Reference to Related Applications

This application is a divisional of U.S. patent application Ser. No. 16/239,201, filed Jan. 3, 2019, which claims priority to U.S. Provisional Patent Application No. 62/668,509, filed May 8, 2018.

### Field of the Invention

This invention relates to supports for portable articles and, more particularly, to a support assembly that allows consumer interaction with a portable article that is displayed upon the support assembly, as at a point of purchase.

### Background Art

Myriad portable electronic articles/devices are displayed in stores in a manner that allows consumers to test operation, identify features, etc. Because of the large number of choices available in most categories of electronic devices, the ability for a consumer to interact with the devices has become critical to successful sales efforts.

In most electronic stores that offer portable electronic devices, different makes and styles of smart phones and tablets are commonly displayed in large numbers. Typically, the smart phones/tablets are displayed on a pedestal-type support in a manner that the screens are substantially unobstructed. Since this type of article is, by its nature, relatively compact in size, and is in the high level expense category, loss due to theft at these displays is an industry problem.

Thus, those that design security systems for this category of device focus on systems that positively secure the devices, are resistant to tampering, and allow relatively unimpeded viewing of the screens and convenient operation of the devices.

Some existing security systems are somewhat complicated and utilize a plurality of capturing or hold-down elements that engage the perimeter edge of the device being displayed. Oftentimes these systems are designed so that a relatively high degree of skill and care are required to assure proper securement of a device. Given the many “touches” of a device during a business day, an improperly secured device is likely to be detected by a would-be thief.

These complicated systems are also undesirable from the standpoint that setup may be time consuming, thereby occupying valuable time of employees. This problem is aggravated by the fact that the devices may be regularly replaced at the displays.

Still further, given that employees that have responsibilities for setting up security systems may be rewarded more for sales efforts than security-related tasks, shortcuts are often taken, resulting in ineffective systems setup, as a result of which devices become more vulnerable to theft.

Another problem that has persisted is that displays with security systems are commonly configured for a particular device size and shape, within a very limited range. Thus, support structures with different dimensional capacities must be inventoried in amounts based upon anticipated numbers of particular devices to be displayed. As devices change, there may be excess or shortage of a certain support type. Due to the ongoing change in device configuration, certain supports may become practically unusable, which necessitates their staging or disposal.

Another problem with displaying this category of device is that it presents a particular challenge to reasonably balance the objectives of effecting security and affording convenience of customer interaction. Were theft not an issue, ideally consumers would be able to pick up and operate individual devices as they would in normal use. Of course, this is not practical, and thus a security structure must be used and must have a very high degree of success in terms of preventing theft, particularly for high-end articles.

One option that is commonly practiced is the use of a cable connection between the device and a base. The device may be supported directly on the base or on a pedestal to optimize display height and angle. The cables may be extendable and retractable whereby a potential purchaser is able to draw the device away from the base/pedestal and readily reorient it to effect inspection and operation.

While these cable systems have been successful, they inherently have the vulnerability that virtually any type of cable can be cut with an appropriate tool. A sophisticated thief might effect separation and depart from a store with merchandise without being caught. Also, the ability to lift and freely move a device makes it more likely that the device might be damaged, as by being dropped or inadvertently being brought into contact with an adjacent object.

Rigid mounts eliminate the issue of cable severance, but are generally restrictive in that the would-be purchaser is often limited in terms of how the displayed device can be observed and handled. For example, pedestal-type displays commonly support the devices in a fixed position that is angled to be displayed at what is perceived to be an optimal orientation. With this arrangement, the would-be purchaser may get little feel for the device and may ultimately lose interest in that device by reason of its limited accessibility.

The industry continues to seek out alternative security system designs for portable articles/devices, and particularly those in the category of the smart phone and tablet. Designers continue to be challenged by the often competing objectives of providing effective security while at the same time allowing interaction with the product that may be adequate enough to trigger a purchase.

### SUMMARY OF THE INVENTION

In one form, the invention is directed to a method of displaying a portable article. The method includes the steps of: obtaining a portable article having a body with a peripheral edge; and obtaining a support assembly. The support assembly has: a) a frame fixed relative to a support and configured to engage the body so as to support the portable article in a display position; and b) a blocking assembly changeable between first and second states. The frame defines a plurality of U-shaped receptacles each configured to receive a part of the peripheral edge of the portable article. With the blocking assembly in the first state, the portable article is slid guidingly against the support assembly in a first direction consistently along a predetermined first path from a pre-assembly position, wherein at least a part of the portable article extends beyond the support assembly in a direction opposite to the first direction, into the display position, wherein the portable article is blocked by the support assembly against separation from the frame other than by movement oppositely to the first direction along the predetermined first path. The step of sliding the portable article into the display position involves directing a straight length of the peripheral edge through and beyond one of the U-shaped receptacles. The support assembly is configured so that with the blocking assembly in the first state, the blocking assembly does not interfere with guided movement of the portable article in the predetermined first path oppositely to the first direction from the display position to away from the support assembly. With the portable article in the display position, the blocking assembly is changed into the second state wherein the blocking assembly blocks movement of the portable article in the display position along the predetermined first path oppositely to the first direction as would allow separation of the portable article from the support assembly.

In one form, the blocking assembly has a blocking component that pivots relative to the frame between first and second positions. The step of changing the blocking assembly into the second state involves changing the blocking assembly from the first position into the second position.

In one form, the portable article has a substantially flat display surface that resides in a reference plane. The blocking component pivots around an axis that is substantially parallel to the reference plane with the portable article in the display position. In the first position the blocking component resides entirely below the reference plane.

In one form, the support assembly further includes a locking assembly. The method further includes the step of operating the locking assembly to releasably maintain the blocking component in the second position.

In one form, the locking assembly has a locked state and a released state. The locking assembly further includes a key. The method further includes the step of using the key to change the locking assembly between the locked and released states.

In one form, the portable article is one of a phone and a tablet.

In one form, first and second of the U-shaped receptacles open towards each other.

In one form, first and second of the U-shaped receptacles open respectively in first and second directions disposed at an angle with respect to each other.

In one form, the angle is approximately 90°. The first and second U-shaped receptacles remain fixed in relationship to each other as the portable article is moved in the predetermined path into the display position.

In one form, first and second of the U-shaped receptacles have at all times a fixed angular relationship with each other.

In one form, the plurality of U-shaped receptacles include first and second U-shaped receptacles opening towards each other and a third U-shaped receptacle. The first, second, and third U-shaped receptacles at all times have a fixed relationship and cooperatively define a combined U-shaped receptacle for the portable article that opens oppositely to the first direction.

In one form, the first predetermined path is a substantially linear path.

In one form, the blocking component defines a U-shaped receptacle into which a part of the peripheral edge of the portable article extends with the portable article in the display position and the blocking component in the second position.

In one form, the blocking component has a portion that overlies the portable article adjacent the peripheral edge of the portable article with the portable article in the display position and the blocking component in the second position.

In one form, the portable article has a power input port. The method further includes the steps of obtaining a connector and operatively connecting the power input port to the connector with the portable article in the display position.

In one form, the connector is fixed to the frame. The method further includes the step of causing the connector to be operatively connected to the power input port as an incident of the portable article being directed along the first predetermined path into the display position.

In one form, the frame defines a U-shaped receptacle that receives a part of the peripheral edge of the body of the portable article with the portable article in the display position. The connector resides within the U-shaped receptacle.

In one form, a power source is provided for the portable article that is operatively connected to the connector.

In one form, the method further includes the step of operatively connecting an alarm system to the connector. The alarm system is configured to generate a detectable alarm signal in the event that either: a) the portable article is separated from the frame; or b) the frame is moved beyond a predetermined distance from a display location.

In one form, a pedestal is connected to the support assembly frame and fixed to a support surface for maintaining the article in the display position in an elevated position over a support surface.

In one form, the portable article is moved within a plane between the pre-assembly and display positions.

In one form, the blocking assembly remains connected to the frame in each of the first and second states.

In one form, the method includes the steps of: obtaining a portable article having a body with a peripheral edge; and obtaining a support assembly for displaying the portable article. The support assembly includes: a) a frame fixed relative to a support and configured to engage the body so as to support the portable article in a display position; and b) a blocking assembly changeable between first and second states. The frame defines a plurality of U-shaped receptacles each configured to receive a part of the peripheral edge of the portable article. With the blocking assembly in the first state, the portable article is slid guidingly against the support assembly in a first direction along a first predetermined path within a plane from a pre-assembly position, wherein at least a part of the portable article extends beyond the support assembly in a direction opposite to the first direction, into the display position, wherein the portable article is blocked by the support assembly against separation from the frame other than by movement oppositely to the first direction along the first path. The step of sliding the portable article into the display position involves directing a straight length of the peripheral edge through and beyond one of the U-shaped receptacles. The blocking assembly is configured so that in the second state the blocking assembly blocks guided movement of the portable article in the display position along the first predetermined path oppositely to the first direction as would allow separation of the portable article from the support assembly. The support assembly has a blocking component. The step of changing the blocking assembly from the first state into the second state involves pivoting the blocking component from the first position into the second position. With the portable article in the display position and the blocking assembly in the second state a portion of the peripheral edge on the body of the portable article remains exposed.

In one form, the frame and portable article are configured so that with the blocking assembly in the first state the portable article is slid guidingly against the support assembly in moving from the pre-assembly position into the display position. The blocking assembly remains connected to the frame in each of the first and second states.

In one form, the frame has a second U-shaped receptacle into and through which a straight length of the peripheral edge of the body moves as the portable article is moved from the pre-assembly position into the display position. The first and second receptacles open towards each other and have a fixed spacing from each other. The portable article in the display position is captively maintained against the frame by the first and second article engaging attachments.

In one form, the frame has a flat support surface. The peripheral edge on the portable article body has substantially parallel first and second spaced edge portions and a third edge portion extending between the first and second edge portions. The support assembly has first, second, and third U-shaped receptacles that cooperatively define a combined U-shaped receptacle and respectively engage and captively hold the first, second, and third edge portions against the flat frame support surface as an incident of the portable article moving from the pre-assembly position into the display position.

In one form, the combined U-shaped receptacle has at all times a fixed shape and size.

In one form, the invention is directed to a method of displaying a portable article. The method includes the steps of: obtaining a portable article with a body having a flat surface and a peripheral edge; obtaining a support assembly. The support assembly has: a) a frame fixed relative to a support; and b) a blocking assembly changeable between first and second states. The frame defines a flat surface. A plurality of L-shaped arms each define in conjunction with the flat surface a U-shaped receptacle. The flat surface and plurality of U-shaped receptacles cooperatively define a U-shaped envelope into which the portable article can be directed to assume a display position wherein the article is blocked from being drawn away from the flat surface by the plurality of L-shaped arms. Translating the portable article from a pre-assembly position separated from the support assembly substantially in a plane and in a first direction causes the portable article to be maintained in the display position wherein the portable article can be separated from the frame only by moving the portable article in the second direction towards the pre-assembly position. With the portable article in the display position, the blocking assembly is changed from the first state into the second state wherein the blocking assembly blocks movement of the portable article in the display position in the second direction.

In one form, a plurality of L-shaped arms have a fixed position on the frame.

In one form, the U-shaped envelope has at all times a fixed size and shape.

### BRIEF DESCRIPTION OF THE DRAWINGS

FIG. 1 is a schematic representation of a portable article with which the present invention can be practiced;

FIG. 2 is a schematic representation of the portable article, as shown in FIG. 1, and showing a typical general shape therefor;

FIG. 3 is a schematic representation of a support assembly, according to the present invention, in combination with the portable article as shown in FIGS. 1 and 2;

FIG. 4 is a side elevation view of one specific form of the inventive support assembly and portable article, as shown in FIGS. 1-3, and with the portable article in a display position;

FIG. 5 is an enlarged, fragmentary, exploded, perspective view showing parts of the frame making up the inventive support assembly of FIG. 4;

FIG. 6 is a front elevation view of the components as shown in FIG. 4;

FIG. 7 is a rear elevation view of the components as shown in FIGS. 4 and 6;

FIG. 8 is an enlarged, perspective view of an article engaging attachment on a frame on the inventive support assembly in FIGS. 4, 6, and 7;

FIG. 9 is an end view of the attachment in FIG. 8;

FIG. 10 is an enlarged, exploded, perspective view of another article engaging attachment on the inventive frame and incorporating a docking feature to provide power and/or alarm capability and with an optional cover assembly for blocking access to a “home button” on a displayed electronic apparatus;

FIG. 11 is a view as in FIG. 10 with the parts assembled;

FIG. 12 is an enlarged, perspective view of another article engaging attachment on the inventive frame and incorporating a blocking component that is movable between first and second positions, with the blocking component in the second position in FIG. 12;

FIG. 13 is a schematic representation of a receptacle formed cooperatively by three article engaging attachments on the inventive frame;

FIG. 14 is an exploded, perspective view of the attachment in FIG. 12;

FIG. 15 is a view as in FIG. 14 but from a different perspective;

FIG. 16 is a partially exploded view of the attachment as shown in FIG. 12 with the blocking component in its second position;

FIG. 17 is a view as in FIG. 16 with the blocking component in its first position;

FIG. 18 is an enlarged, fragmentary, side elevation view of the inventive support assembly with the portable article in a display position and with the blocking component in its first position;

FIG. 19 is a view as in FIG. 18 with the blocking component in its second position;

FIG. 20 is an exploded perspective view of the attachment on the frame as shown in FIGS. 10 and 11;

FIG. 21 is a side elevation view of the attachment in FIG. 20 with one side thereof removed;

FIG. 22 is an enlarged, fragmentary, cross-sectional view of the support assembly and displayed article taken along line 22-22 of FIG. 6;

FIG. 23 is an enlarged, front, fragmentary view of the inventive support assembly with the article in the display position and the cover assembly as shown in FIGS. 10 and 11 overlying a home button on the displayed article; and

FIG. 24 is a rear elevation view of a modified form of support assembly with the portable article in a display position and with the docking structure replaced with separate, different, article engaging attachments.

### DETAILED DESCRIPTION OF THE PREFERRED EMBODIMENT

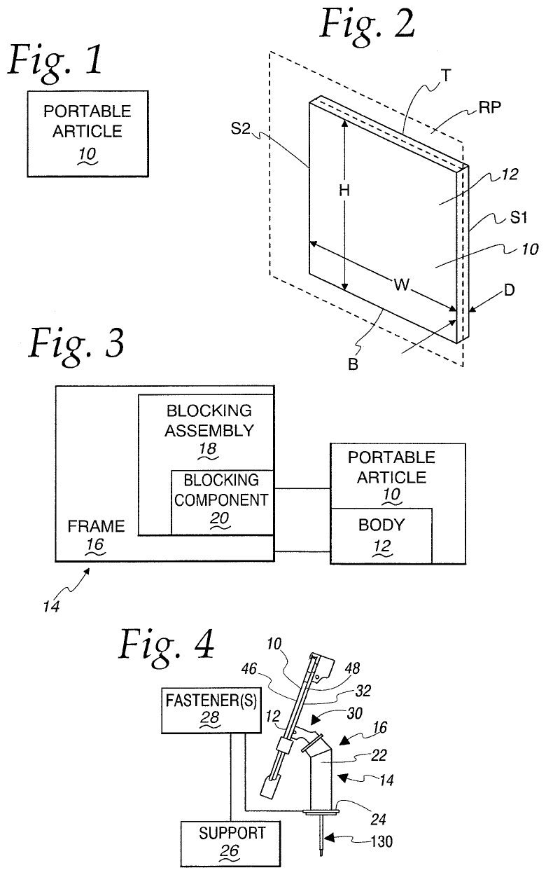

FIG. 1 is a generic representation of a portable device/article 10 of the type displayed and secured according to the present invention. The portable article 10 may be any type of article that is commonly displayed at point of purchase for consumers to inspect and potentially operate to assist a purchasing decision. While not so limited, the portable article 10 will be described herein as an electronic component, such as a tablet, phone, etc.

Generally, the portable article 10 will have a configuration as nominally represented by the shape shown in FIG. 2. That is, the portable article has a body 12 with a generally flat, squared shape with a height H, a width W, and a depth D that, for purposes of simplicity, can be said to reside in a reference plane RP. Generally, the peripheral top and bottom edges/surfaces T, B are parallel, as are the opposite, peripheral side edges/surfaces S1, S2.

As shown in FIG. 3, also in generic form, the invention is directed to the combination of the portable article 10 and a support assembly at 14 for displaying the portable article 10. The support assembly 14 has a frame 16 configured to engage the article body 12 so as to support the article in a display position.

The support assembly 14 further includes a blocking assembly 18 changeable between first and second states. The frame 16 and portable article 10 are configured so that with the blocking assembly in a first state, the portable article 10 can be slid guidingly against the support assembly in a first direction along a first path from a pre-assembly position into the display position. The frame 16 and portable article 10 are further configured so that with the portable article 10 in the display position, the portable article 10 is blocked by the support assembly 14 against separation from the frame 16 other than by movement oppositely to the first direction along the first path.

The blocking assembly 18 is configured so that in its second state, the blocking assembly 18 blocks movement of the portable article 10 in the display position along the first path oppositely to the first direction as would allow separation of the portable article 10 from the support assembly 14.

The blocking assembly 18 has a blocking component 20 that moves relative to the frame 16 between first and second positions. The blocking assembly 14 is in the first state with the blocking component 20 in the first position and in the second state with the blocking component 20 in the second position.

In one form, the support assembly 14 is configured so that with the blocking assembly 18 in the first state, the blocking assembly 18 does not interfere with movement of the portable article 10 moving in the first path oppositely to the first direction from the display position to away from the support assembly 14.

The portable article 10 may move within the reference plane RP between the pre-assembly and display positions. The blocking assembly 18 may be configured so that the reference plane RP does not intersect the blocking assembly 18 with the blocking assembly in its first state to thereby permit unimpeded separation of the portable article 10 from the support assembly 14.

In one form, the blocking component 20 pivots between its first and second positions. However, this pivot connection is not required.

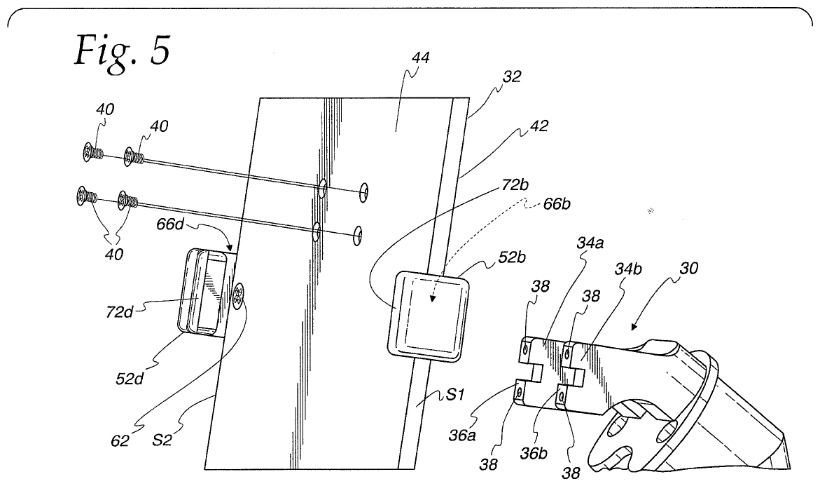

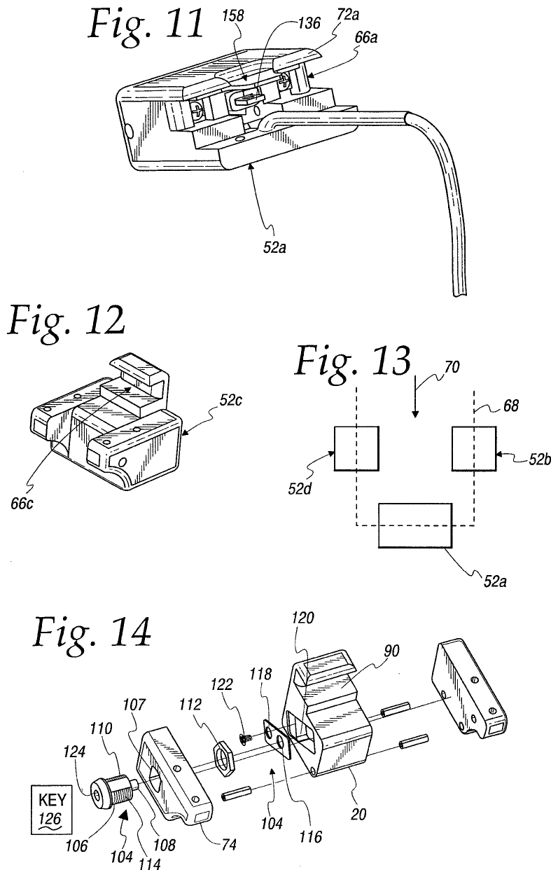

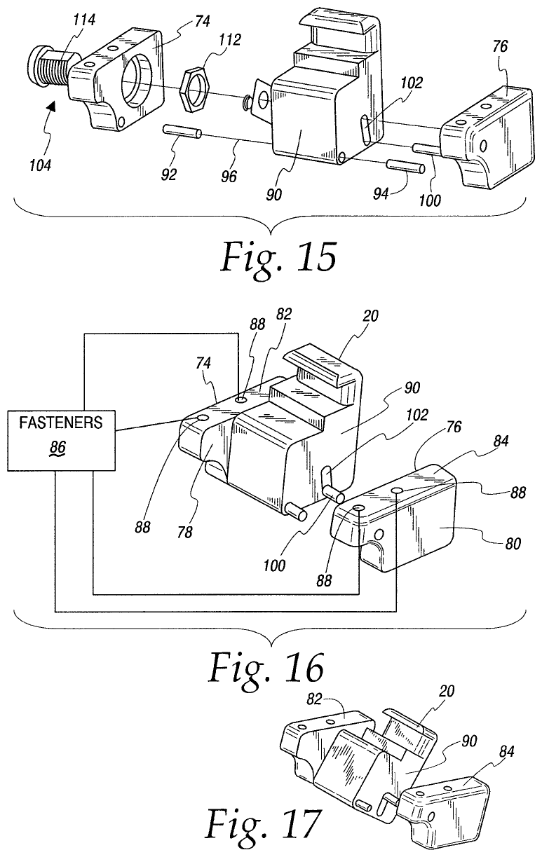

Referring now to FIGS. 4-23, a specific form of support assembly 14, according to the present invention, will be described, with it being understood that this is but exemplary of the myriad different variations contemplated within the schematic showings of the support assembly 14 in FIG. 3. The schematic representation is intended to encompass the specific forms described hereinbelow as well as variations of the depicted components and their interactions within the generic showing of FIG. 3.

As shown in FIGS. 4-23, the exemplary support assembly 14 has a pedestal/base 22 with an enlarged, bottom flange 24 that can be secured to an appropriate, fixed, support 26, as at a point-of-purchase location. At least one fastener 28 may be used to effect anchoring of the flange 24.

The upper portion of the pedestal/base 22 has a mounting assembly at 30 which is connected to a pad/base 32. In this embodiment, the mounting assembly 30 is bifurcated to produce spaced, cantilevered, mounting arms 34a, 34b, respectively with flat surfaces 36a, 36b, which reside in a common plane.

The arms 30 have threaded bores 38 to receive threaded fasteners 40 directed from the front of the pad/base 32 through the pad/base 32. By tightening the fasteners 40, the arm surfaces 36a, 36b can be drawn flushly against a back surface 42 of the pad/base 32.

In the depicted embodiment, the pedestal/base 22, the mounting assembly 30 thereon, and the pad/base 32 make up part of the frame 16, configured so that a flat front surface 44 on the pad/base 32 has an angled orientation as shown clearly in FIG. 4. The portable article 10 in its display position is placed against the front surface 44. While a fixed angular relationship between the pad/base 32 and pedestal/base 22 is shown, this is not required, as an adjustment capability might be incorporated into the design.

Typical of the articles displayed on the support assembly 14 is one as depicted (phone, table, etc.) with a flat, front, display surface 46 that resides in a plane that is substantially parallel to the reference plane RP with the article in the display position of FIG. 4. The display angle is selected to present the display surface 46 at an optimal viewing angle. The body 12 of the article 10 depicted has a flat back surface 48 that is facially placed against the front surface 44 of the pad/base 32 with the article 10 in the display position.

To maintain the article 10 consistently in its display position, the support assembly 14 is configured to define receptacles that accommodate the peripheral edge region at 50 of the article body 12 adjacent to surfaces at the peripheral edge portions T, B, S1, S2, as identified generically in FIG. 2.

In this embodiment, the receptacles make up part of the frame 16 and are defined by separate article engaging attachments 52a, 52b, 52c, 52d connected to the pad/base 32. Of course, the same configurations as described hereinbelow might be made by a unitary construction at one or all of the locations where there are receptacles formed.

Attachments 52b, 52d have the same construction, as see most clearly in FIGS. 8 and 9, in which exemplary attachment 52d is shown. The attachment 52d has a mounting portion at 54 with transverse flat surfaces 56, 58. The surface 58 is abuttable to the edge surface S2 on the pad/base 32 with the surface 56 abutted to the back surface 42 on the pad/base 32. A fastener 60 extends through the pad/base 32 from the front thereof and into a blind bore 62 in the attachment 52d to effect fixed securement thereof.

An anchoring portion 64 of the attachment 52d extends from the mounting portion 54 and defines one of the aforementioned receptacles 66d that receives a part of the peripheral edge region 50 of the article 10. In this embodiment, the attachment 52d is constructed so that the anchoring portion 64 extends laterally beyond the pad/base 32. This is not a requirement, nor is it a requirement that the attachment 52 by itself define the receptacle 66d, as part of the receptacle could be defined by the front surface 44 of the pad/base 32 of which a part of the attachment 52d may overlie to define the receptacle.

In this embodiment, the U-shaped receptacles 66b, 66d open laterally towards each other and are at the same vertical location in relationship to the displayed article 10. This vertical alignment is not required, nor is the design limited to the particular number or location of attachments. It is desirable that at least the two attachments 52b, 52d be provided to confine lateral movement of the displayed article 10.

As shown in FIGS. 10-12, the attachments 52a, 52c respectively define U-shaped receptacles 66a, 66c opening oppositely and respectively upwardly and downwardly in relationship to the displayed article 10. In this case, the receptacles 66a, 66c open in directions angled with respect to the direction of opening of the receptacles 66b, 66d. As depicted, with the particular article configuration, the angle is approximately 90°. Different angles might be utilized.

While not required, in this embodiment, each of the receptacles 66a, 66b, 66c, 66d has a fixed angular relationship with the other receptacles 66a, 66b, 66c, 66d. However, some of the angular relationships may be fixed while others are variable.

A number of attachments 52 at the top and bottom of the pad/base 32 and the displayed article 10 may be different from those in the depicted embodiment.

The attachment 52a has the same general configuration as the above-described attachments 52b, 52d but is modified to perform an electronic docking function, as hereinbelow described.

As shown partially schematically in FIG. 13, the attachments 52a, 52b, 52d cooperatively define a U-shaped receptacle, approximated by the dotted line shown at 68. This arrangement allows the portable article 10 to be placed against the flat front surface 44 of the pad/base 32 and slid guidingly downwardly thereagainst, initially into the U-shaped receptacles 66b, 66d, and eventually into the receptacle 66a in a substantially linear path, and in a first direction, as indicated by the arrow 70 in FIG. 13. Once this display position is realized, portions 72a, 72b, 72d of the attachments 52a, 52b, 52d overlie the front display surface 46 on the article 10 and thereby captively maintain the body 12 of the article 10 against the pad/base 32.

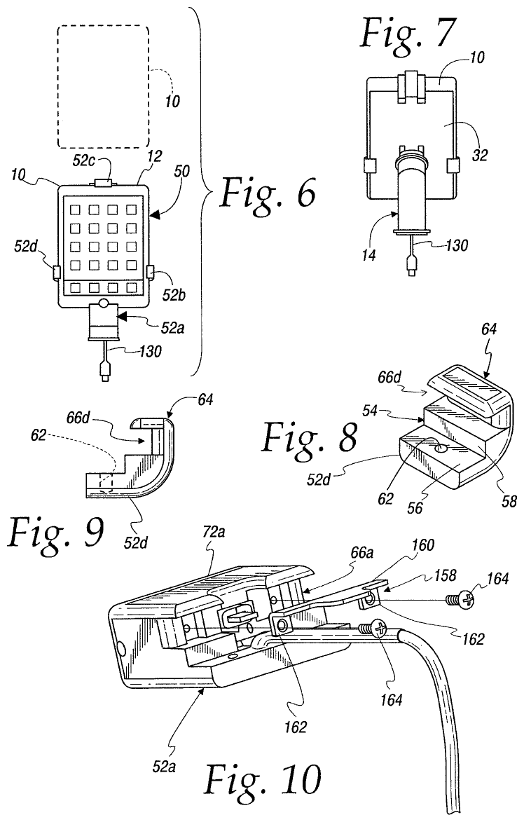

The portions 72 are preferably made to have adequate overlap of the displayed article 10 to firmly anchor the same without significantly obstructing viewing of the front article display. Accordingly, by moving the portable article 10 from a preassembly position, as shown in dotted lines in FIG. 6, in a linear path as indicated by the arrow 70 in FIG. 13, into the display position, the portable article 10 is blocked by the support assembly 14 against separation from the frame 16 other than by movement oppositely to the direction indicated by the arrow 70 in FIG. 13. While not required, in the depicted form, the path of the article 10 between the preassembly and display positions is substantially linear.

The attachment 52c, in addition to defining the receptacle 66c, also defines the blocking assembly 18, as shown in detail in FIGS. 14-19.

The blocking assembly 18 consists of the aforementioned blocking component 20 that is mounted on the pad/base 32, making up part of the frame 16, through a pair of mounting components 74, 76. The mounting components 74, 76 have bodies 78, 80 that are substantially mirror images of each other. The blocking component 20 is operatively supported between the mounting components 74, 76 that are fixed at spaced locations to the back surface 42 of the pad/base 32. The components 74, 76 respectively have flat surfaces 82, 84 which are mounted to bear against the back surface 42 of the pad/base 32 and secured by fasteners 86 extending from the front of the pad/base 32, through the pad/base 32, into bores 88 in the mounting components 74, 76.

The blocking component 20 has a body 90 that is mounted through coaxial pins 92, 94 that extend into the body 90 and respectively into the mounting components 74, 76 to thereby cooperatively guide the body 90 for pivoting movement around an axis 96 defined by the pins 92, 94. The axis 96 is parallel to the reference plane RP with the article 10 in the display position.

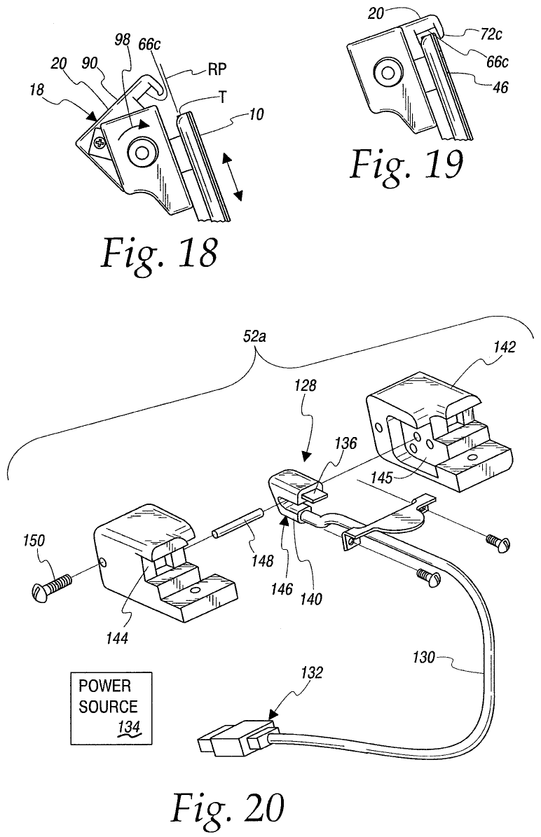

With this arrangement, the blocking component 20/body 90 may be considered to be part of the frame 16, although it is not a fixed part thereof and thus may alternatively be considered to be separate from the frame 16. Through this mounting arrangement, the body 90/blocking component 20 is pivotable between a first position as shown in FIGS. 17 and 18, and a second position, as shown in FIGS. 16 and 19, respectively representing the first and second states for the blocking assembly 18.

As seen most clearly in FIG. 18, with the blocking assembly 18 in the first state, the article 10 can be slid in the aforementioned first linear path between preassembly and display positions without interference between the article 10 and the body 90. That is, the aforementioned reference plane RP, within which the article 10 moves, does not intersect the blocking assembly 18 with the blocking assembly in the first state of FIG. 18.

With the article 10 in the display position, the blocking component 20 can be pivoted in the direction of the arrow 98 around the axis 96 to thereby place the blocking component 20 in its second position, as shown in FIG. 19. In the second position, corresponding to the second state for the blocking assembly 18, the top edge surface T nests in the U-shaped receptacle 66c and the portion 72c overlies the edge region of the display surface 46.

Accordingly, with the article in the display position and the blocking component 20 in its second position, a part of the peripheral edge region of the portable article resides in each of the receptacles 66a, 66b, 66c, 66d to prevent the article 10 from being drawn away from the pad/base 32. The blocking component 20 blocks movement of the portable article 10 from the display position oppositely to the aforementioned first direction as would allow the article to be separated from the support assembly 14.

Accordingly, a user is allowed to simply press fit the portable article 10 into the aforementioned U-shaped receptacle 68 whereupon a simple pivoting of the blocking component 20 limits opposite movement of the article from its display position.

Once it is desired to separate the portable article 10 from the support assembly 14, the blocking component 20 can be moved back into the first position of FIG. 18, whereby the blocking assembly 18 does not interfere with movement of the portable article out of the display position to fully away from the support assembly 14.

The range of pivoting movement of the blocking component 20 is dictated by a pin 100 on the mounting component 76 that projects into an elongate slot 102 on one side of the body 90. The slot length is selected to fix the desired pivot range for the blocking component 20.

A locking assembly 104 is provided to releasably maintain the blocking component 20 in its second position. The locking assembly 104 consists of a lock assembly 106 with an extendable plunger 108. A body 110 of the lock assembly 106 is mounted in a complementary, non-round bore 107 within, and thereby keyed against rotation relative to, the mounting component 74 and secured thereto with a nut 112 engaging outer threads 114 on the body 110.

The plunger 108 is extendable through a complementarily-shaped opening 116 in a reinforcing plate 118. The plate 118 is mounted to the body 90 to project across a complementarily-shaped cavity 120. With the plate 118 fixed to the body 90 through a suitable fastener 122, the plunger 108 can extend without obstruction through the opening 116 and into the cavity 120, with the plate 118 thereby preventing the blocking component 20 from moving out of its second position, as shown in FIG. 19.

In one preferred form, the plunger 108 is extended through a push-in actuator 124. Once the actuator 124 is pushed in to extend the plunger 108, the locking assembly 104 is in a locked state and can be changed to a released state only with a security key 126.

The push-in lock feature is desirable from the standpoint of facilitating locking, as by an employee. In a number of simple steps, the employee can guide the article 10 into its display position and pivot the blocking component 20 from its FIG. 18 position into its FIG. 19 position and thereafter effect locking by pressing in on the actuator 124. No separate keys, fasteners, tools, etc. are required to effect mounting and securement of the article 10.

The use of the plate 118 makes it feasible to form the blocking component 20 of a non-metal material, which might otherwise be prone to being compromised if a would-be thief attempted to force the blocking component 20 from its second position back into its first position to effect release of the article 10.

Another advantage of this construction is that the blocking component 20 remains at all times connected to the frame 16 so that it is not prone to being lost or misplaced.

As noted above, the support assembly 14 may additionally perform the function of a docking station in which the displayed portable article 10 can be powered.

As shown most clearly in FIGS. 10, 11, and 20-22, the attachment 52a may incorporate an electrical connector assembly 128. The connector assembly 128 consists of a cord 130 with a connector 132 to connect to a power source 134 and a separate connector 136 that can be directed into a power input port 138 on the portable article 10 to electrically connect the article 10 to the power source 134.

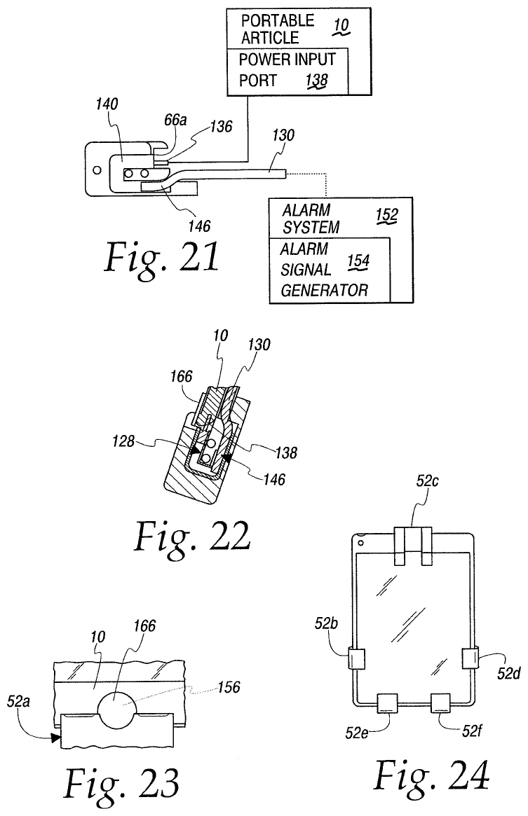

To rigidify the mounting of the connector 136, a molded body 140 is formed around a part of the connector 136 and a discrete length of the cord 130 with the discrete cord length in a “U” shape, as seen most clearly in FIG. 21. The body 140 is captive between two body parts 142, 144 that are joined to define the attachment 52a. The body 140 and bent length of the cord 130 at 146 are pressed into a complementarily-shaped receptacle 145 defined by one or both of the body parts 142, 144. The body parts are aligned through a pin 148 and maintained together by a threaded fastener 150.

The support assembly 14 is configured so that as the lower portion of the article body 12 is advanced guidingly into the U-shaped receptacle 66a, the contact 136 is aligned with and moves into the power input port 138 to establish electrical connection between the portable article 10 and the power source 134.

As a further option, an alarm system 152 may be incorporated and operatively engaged with the article through the cord 130. The cord 130 may thus be used to enable powering and/or alarm functions.

The alarm system 152 may incorporate a detectable alarm signal generator 154 that generates a detectable alarm signal in the event that either: a) the portable article 10 is separated from the frame 16; or b) the frame 16 is moved beyond a predetermined distance from the display location.

Another optional feature is the incorporation of a “home button” cover that prevents user operation of the apparatus 10 through a home button 156, as shown in FIG. 23. In this embodiment, a cover assembly at 158 consists of a body 160 with mounting tabs 162 secured by fasteners 164 within the U-shaped receptacle 66a on the attachment 52a.

With the cover assembly 158 assembled, as shown additionally in FIG. 22, a flat plate 166 thereon directly overlies the home button 156 to prevent depression thereof.

In FIG. 24, a modified form of support assembly is shown wherein the alarm/power feature, integrated through the attachment 52a, is eliminated. Instead, attachments 52e, 52f, having the same configuration as the attachment 52b, 52d, are utilized. It would be possible to use a single one of the attachments 52e, 52f.

The basic operation of the support assembly shown in FIG. 24 is otherwise the same as that described above with the docking arrangement for power and/or alarm.

The foregoing disclosure of specific embodiments is intended to be illustrative of the broad concepts comprehended by the invention.

1. A method of displaying a portable article, the method comprising the steps of:
obtaining a portable article having a body with a peripheral edge;
obtaining a support assembly, the support assembly comprising:
a) a frame fixed relative to a support and configured to engage the body so as to support the portable article in a display position,
the frame defining a plurality of U-shaped receptacles each configured to receive a part of the peripheral edge of the portable article; and
b) a blocking assembly changeable between first and second states,
with the blocking assembly in the first state, sliding the portable article guidingly against the support assembly in a first direction consistently along a predetermined first path from a pre-assembly position, wherein at least a part of the portable article extends beyond the support assembly in a direction opposite to the first direction, into the display position wherein the portable article is blocked by the support assembly against separation from the frame other than by movement oppositely to the first direction along the predetermined first path,
wherein the step of sliding the portable article into the display position comprises directing a straight length of the peripheral edge through and beyond one of the U-shaped receptacles,
the support assembly configured so that with the blocking assembly in the first state, the blocking assembly does not interfere with guided movement of the portable article in the predetermined first path oppositely to the first direction from the display position to away from the support assembly,
with the portable article in the display position, changing the blocking assembly into the second state wherein the blocking assembly blocks movement of the portable article in the display position along the predetermined first path oppositely to the first direction as would allow separation of the portable article from the support assembly.

2. The method of displaying a portable article according to claim 1 wherein the blocking assembly comprises a blocking component that pivots relative to the frame between first and second positions and the step of changing the blocking assembly into the second state comprises changing the blocking assembly from the first position into the second position.

3. The method of displaying a portable article according to claim 2 wherein the portable article has a substantially flat display surface that resides in a reference plane and the blocking component pivots around an axis that is substantially parallel to the reference plane with the portable article in the display position and in the first position the blocking component resides entirely below the reference plane.

4. The method of displaying a portable article according to claim 2 wherein the support assembly further comprises a locking assembly and further comprising the step of operating the locking assembly to releasably maintain the blocking component in the second position.

5. The method of displaying a portable article according to claim 4 wherein the locking assembly has a locked state and a released state and the locking assembly further comprises a key and further comprises the step of using the key to change the locking assembly between the locked and released states.

6. The combination according to claim 1 wherein the portable article is one of a phone and a tablet.

7. The method of displaying a portable article according to claim 1 wherein first and second of the U-shaped receptacles open towards each other.

8. The method of displaying a portable article according to claim 1 wherein first and second of the U-shaped receptacles open respectively in first and second directions disposed at an angle with respect to each other.

9. The method of displaying a portable article according to claim 8 wherein the angle is approximately 90° and the first and second U-shaped receptacles remain fixed in relationship to each other as the portable article is moved in the predetermined path into the display position.

10. The method of displaying a portable article according to claim 6 wherein first and second of the U-shaped receptacles have at all times a fixed angular relationship with each other.

11. The method of displaying a portable article according to claim 6 wherein the plurality of U-shaped receptacles comprises first and second U-shaped receptacles opening towards each other and a third U-shaped receptacle, the first, second, and third U-shaped receptacles at all times having a fixed relationship and cooperatively defining a combined U-shaped receptacle for the portable article that opens oppositely to the first direction.

12. The method of displaying a portable article according to claim 11 wherein the first predetermined path is a substantially linear path.

13. The method of displaying a portable article according to claim 2 wherein the blocking component defines a U-shaped receptacle into which a part of the peripheral edge of the portable article extends with the portable article in the display position and the blocking component in the second position.

14. The method of displaying a portable article according to claim 2 wherein the blocking component has a portion that overlies the portable article adjacent the peripheral edge of the portable article with the portable article in the display position and the blocking component in the second position.

15. The method of displaying a portable article according to claim 1 wherein the portable article has a power input port and further comprising the steps of obtaining a connector and operatively connecting to the power input port to the connector with the portable article in the display position.

16. The method of displaying a portable article according to claim 15 wherein the connector is fixed to the frame and further comprising the step of causing the connector to be operatively connected to the power input port as an incident of the portable article being directed along the first predetermined path into the display position.

17. The method of displaying a portable article according to claim 16 wherein the frame defines a U-shaped receptacle that receives a part of the peripheral edge of the body of the portable article with the portable article in the display position and the connector resides within the U-shaped receptacle.

18. The method of displaying a portable article according to claim 15 wherein a power source is provided for the portable article that is operatively connected to the connector.

19. The method of displaying a portable article according to claim 15 further comprising the step of operatively connecting an alarm system to the connector, the alarm system configured to generate a detectable alarm signal in the event that either: a) the portable article is separated from the frame; or b) the frame is moved beyond a predetermined distance from a display location.

20. The method of displaying a portable article according to claim 1 wherein a pedestal is connected to the support assembly frame and fixed to a support surface for maintaining the article in the display position in an elevated position over a support surface.

21. The method of displaying a portable article according to claim 1 wherein the portable article is moved within a plane between the pre-assembly and display positions.

22. The method of displaying a portable article according to claim 2 wherein the blocking assembly remains connected to the frame in each of the first and second states.

23. A method of displaying a portable article, the method comprising the steps of:
obtaining a portable article having a body with a peripheral edge; and
obtaining a support assembly for displaying the portable article, the support assembly comprising:
a) a frame fixed relative to a support and configured to engage the body so as to support the portable article in a display position,
the frame defining a plurality of U-shaped receptacles each configured to receive a part of the peripheral edge of the portable article; and
b) a blocking assembly changeable between first and second states,
with the blocking assembly in the first state, sliding the portable article guidingly against the support assembly in a first direction along a first predetermined path within a plane from a pre-assembly position, wherein at least a part of the portable article extends beyond the support assembly in a direction opposite to the first direction, into the display position wherein the portable article is blocked by the support assembly against separation from the frame other than by movement oppositely to the first direction along the first path,
wherein the step of sliding the portable article into the display position comprises directing a straight length of the peripheral edge through and beyond one of the U-shaped receptacles,
the blocking assembly configured so that in the second state the blocking assembly blocks guided movement of the portable article in the display position along the first predetermined path oppositely to the first direction as would allow separation of the portable article from the support assembly,
wherein the support assembly comprises a blocking component and the step of changing the blocking assembly from the first state into the second state comprises pivoting the blocking component from the first position into the second position,
wherein with the portable article in the display position and the blocking assembly in the second state a portion of the peripheral edge on the body of the portable article remains exposed.

24. The method of displaying a portable article according to claim 23 wherein the frame and portable article are configured so that with the blocking assembly in the first state the portable article is slid guidingly against the support assembly in moving from the pre-assembly position into the display position and the blocking assembly remains connected to the frame in each of the first and second states.

25. The method of displaying a portable article according to claim 23 wherein the frame has a second U-shaped receptacle into and through which a straight length of the peripheral edge of the body moves as the portable article is moved from the pre-assembly position into the display position, the first and second receptacles opening towards each other and having a fixed spacing from each other, whereby the portable article in the display position is captively maintained against the frame by the first and second article engaging attachments.

26. The method of displaying a portable article according to claim 23 wherein the frame has a flat support surface, the peripheral edge on the portable article body has substantially parallel first and second spaced edge portions and a third edge portion extending between the first and second edge portions, and the support assembly has first, second, and third U-shaped receptacles that cooperatively define a combined U-shaped receptacle and respectively engage and captively hold the first, second, and third edge portions against the flat frame support surface as an incident of the portable article moving from the pre-assembly position into the display position.

27. The method of displaying a portable article according to claim 26 wherein the combined U-shaped receptacle has at all times a fixed shape and size.

28. A method of displaying a portable article, the method comprising the steps of:
obtaining a portable article with a body having a flat surface and a peripheral edge;
obtaining a support assembly, the support assembly comprising:
a) a frame fixed relative to a support,
the frame defining a flat surface and a plurality of L-shaped arms each defining in conjunction with the flat surface a U-shaped receptacle; and
b) a blocking assembly changeable between first and second states,
the flat surface and plurality of U-shaped receptacles cooperatively defining a U-shaped envelope into which the portable article can be directed to assume a display position wherein the article is blocked from being drawn away from the flat surface by the plurality of L-shaped arms;
translating the portable article from a pre-assembly position separated from the support assembly substantially in a plane and in a first direction to cause the portable article to be maintained in the display position wherein the portable article can be separated from the frame only by moving the portable article in the display position in the second direction towards the pre-assembly position,
with the portable article in the display position, changing the blocking assembly from the first state into the second state wherein the blocking assembly blocks movement of the portable article in the display position in the second direction.

29. The method of displaying a portable article according to claim 28 wherein a plurality of L-shaped arms have a fixed position on the frame.

30. The method of displaying a portable article according to claim 28 wherein the U-shaped envelope has at all times a fixed size and shape.
